(19) United States
(12) Patent Application Publication
(10) Pub. No.: US 2026/0076276 A1
(43) Pub. Date: Mar. 12, 2026

(54) SOLDERLESS AND PRESSURE CONTACT CONNECTION

(71) Applicant: Littelfuse, Inc., Rosemont, IL (US)

(72) Inventors: Tiburcio A. Maldo, Cebu (PH); Rhodri Hughes, Swindon (GB); Robert Ebido, Batangas (PH); Jeff Grozen, Muntinlupa City (PH); Josef Colquin A. Chua, Batangas (PH); Domingo Atienza, JR., Batangas (PH)

(73) Assignee: Littelfuse, Inc., Rosemont, IL (US)

(21) Appl. No.: 19/391,134

(22) Filed: Nov. 17, 2025

Related U.S. Application Data
(62) Division of application No. 17/862,692, filed on Jul. 12, 2022, now Pat. No. 12,500,151.

(51) Int. Cl. H01L 23/498; H01L 21/48; H01L 23/00

(52) U.S. Cl. CPC H10W 90/701; H10W 70/65; H10W 70/093; H10W 90/734

(57) ABSTRACT

A pressure contact assembly includes a power substrate, a chip, and a lead. The power substrate has a surface connected to a ceramic tile and a cavity. The chip is soldered to the surface. The lead is to be inserted into the cavity and has a top portion to connect to an external device and a bottom portion to fit into the cavity.

### CROSS-REFERENCE TO RELATED APPLICATION

This application is a divisional of U.S. application Ser. No. 17/862,692, filed Jul. 12, 2022, entitled “SOLDERLESS AND PRESSURE CONTACT CONNECTION,” which application is incorporated herein by reference in its entirety.

### FIELD OF THE DISCLOSURE

Embodiments of the present disclosure relate to direct copper bonded (DCB) and active metal brazed (AMB) substrates and, more particularly, to soldering issues for these substrates.

### BACKGROUND

Substrates for power electronics are different than printed circuit boards used for low power microelectronics. The power electronics substrate both provides the interconnections to form an electrical circuit and cool the components. Power electronic substrates carry higher currents and provide a higher voltage isolation (up to several thousand volts), as compared to microelectronic counterparts, and operate over a wide temperature range (e.g., up to 200° C.).

Direct bonded copper (DBC), also known as direct copper bonded (DCB) substrates, have very good thermal conductivity, and are thus suitable for power modules. DCBs are composed of a ceramic tile with a sheet of copper bonded to one or both sides of the ceramic tile. Suitable for smaller lots, active metal brazed (AMB) substrates involve the attachment of thick metal layers to ceramic plates. Insulated metal substrates (IMS) are also used for power modules and consist of a metal baseplate covered by a thin layer of dielectric and a layer of copper. IMS are single-sided substrates.

When bonding a power electronics substrate to a power lead, there may exist system reliability issues with the soldering. A phenomenon known as “cold solder” can compromise the bond between the power lead and the substrate over time, particularly when the power electronics substrate is operating in a harsh environment.

It is with respect to these and other considerations that the present improvements may be useful.

### SUMMARY

This Summary is provided to introduce a selection of concepts in a simplified form that are further described below in the Detailed Description. This Summary is not intended to identify key or essential features of the claimed subject matter, nor is it intended as an aid in determining the scope of the claimed subject matter.

An exemplary embodiment of a pressure contact assembly in accordance with the present disclosure may include a power substrate, a chip, and a lead. The power substrate has a surface connected to a ceramic tile and a cavity. The chip is soldered to the surface. The lead is to be inserted into the cavity and has a top portion to connect to an external device and a bottom portion to fit into the cavity.

Another exemplary embodiment of a pressure contact assembly in accordance with the present disclosure may include a lead and a power substrate. The lead has a first portion and a second portion connected to the first portion. The first portion connects to an external device. The second portion is perpendicular to the first portion and has a modification to its smooth surface. The power substrate has a first surface connected to a ceramic tile. The first surface has a cavity inside which the modification is press-fit.

### BRIEF DESCRIPTION OF THE DRAWINGS

FIGS. 1A-1B are diagrams illustrating the cold solder phenomenon, in accordance with the prior art;

FIG. 2 is a diagram illustrating a press-fit solution for bonding components to a printed circuit board, in accordance with the prior art;

FIGS. 3A-3B are diagrams illustrating soldering of components to a power substrate, in accordance with the prior art;

FIGS. 4A-4D are diagrams illustrating a pressure contact assembly, in accordance with exemplary embodiments;

FIGS. 5A-5B are diagrams illustrating resistance welding used with the pressure contact assembly of FIGS. 4A-4D, in accordance with exemplary embodiments;

FIGS. 6A-6C are diagrams of a pressure contact assembly, in accordance with exemplary embodiments;

FIGS. 7A-7B are diagrams of a pressure contact assembly, in accordance with exemplary embodiments;

FIGS. 8A-8C are diagrams of a pressure contact assembly, in accordance with exemplary embodiments;

FIGS. 9A-9C are diagrams of a pressure contact assembly, in accordance with exemplary embodiments;

FIGS. 10A-10D are diagrams of a pressure contact assembly, in accordance with exemplary embodiments; and

FIGS. 11A-11D are diagrams of a pressure contact assembly, in accordance with exemplary embodiments.

### DETAILED DESCRIPTION

Several embodiments of pressure contact assemblies are disclosed herein. The pressure contact assemblies each feature a power substrate having a ceramic tile sandwiched between two DCB or AMB surfaces or a power substrate having a ceramic tile disposed atop an insulated metal substrate. The power substrate has one or more cavities etched out of the top surface and may feature both over-etches and under-etches, where the under-etches may be half-etches, in some embodiments. The power lead (terminal) is adapted to have a top portion that is much like prior art leads, whereas the bottom portion is modified to be fit into the one or more cavities in a variety of ways. Modifications are made to the ceramic tile to improve the ability of the power substrates to support pressure contact assembly.

For the sake of convenience and clarity, terms such as “top”, “bottom”, “upper”, “lower”, “vertical”, “horizontal”, “lateral”, “transverse”, “radial”, “inner”, “outer”, “left”, and “right” may be used herein to describe the relative placement and orientation of the features and components, each with respect to the geometry and orientation of other features and components appearing in the perspective, exploded perspective, and cross-sectional views provided herein. Said terminology is not intended to be limiting and includes the words specifically mentioned, derivatives therein, and words of similar import.

As used herein, power substrates refer variously to direct bonded copper (DBC), also known as direct copper bonded (DCB) substrates, active metal brazed (AMB) substrates, and insulated metal substrates (IMS). The principles shown and described herein may refer to any of these types of substrates. For simplicity, these substrates are referred to as power substrates.

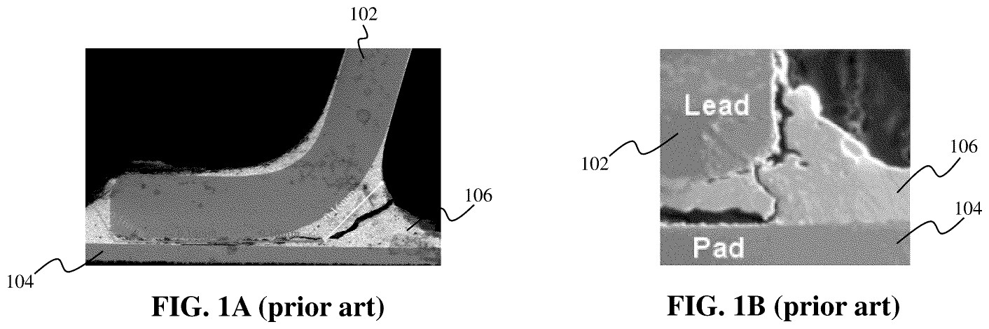

FIGS. 1A-1B are representative drawings of a cold solder problem experienced with power substrates, according to the prior art. FIG. 1A shows a lead (terminal) 102 partially surrounded by solder 106, where the solder 106 attaches the lead to a pad 104 of a power substrate. FIG. 1B is a close-up view of the lead 102, solder 106, and pad 104. In both illustrations, cracks have formed in the solder 106, a phenomenon known as cold solder. Cold solder occurs when the solder cracks, which may occur over time, and is more likely to occur in harsh environments. If the cracks become large enough, the lead 102 is no longer able to form an electrical connection with the pad 104. Thus, the solder 106 is no longer functioning as intended, causing the electronic circuit to become unreliable.

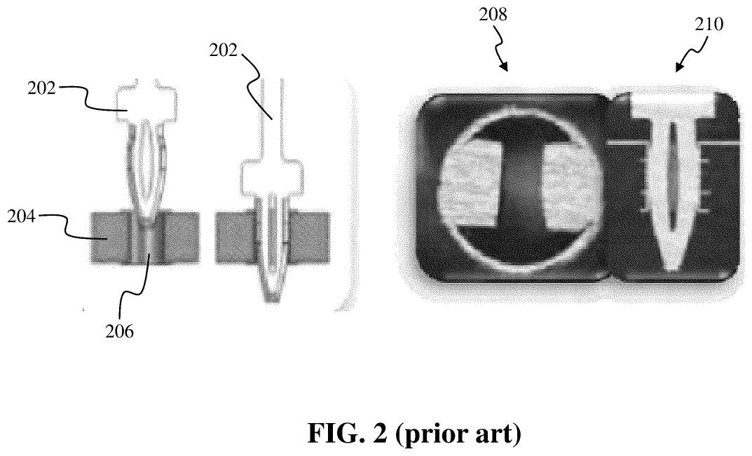

FIG. 2 is a representative drawing of a press-fit solution used to replace soldering in printed circuit boards (PCBs), according to the prior art. A lead (terminal) 202 is shaped to fit securely into an aperture 206 of a PCB 204. The lead 202 is slender at one end, the end to be inserted into the aperture 206, but more bulbous at a center portion, where the diameter of the more bulbous portion is slightly larger than the diameter of the aperture 206. Once the lead 202 is press-fit into the aperture 206 of the PCB 204, the bulbous portion partially compresses in the aperture, forming a tight fit in the PCB 204. A top view 208 and a side view 210 are also shown.

Though there are variations, PCBs are typically made using a material known as FR4 (fire-retardant 4), which is a composite material consisting of woven fiberglass cloth combined with an epoxy resin binder. PCBs thus have some flexibility, which makes them suitable for press-fitting leads through their structure. Power substrates, on the other hand, are made using metal and ceramic, which are less flexible materials. Adding via holes in a power substrate is doable and the press fit pin can be inserted into the via holes. However, the components on the power substrate will lose the electrical isolation that characterizes power substrates, thus defeating the purpose of using power substrates. The traditional press-fitting illustrated in FIG. 2 is thus not suitable for power substrates.

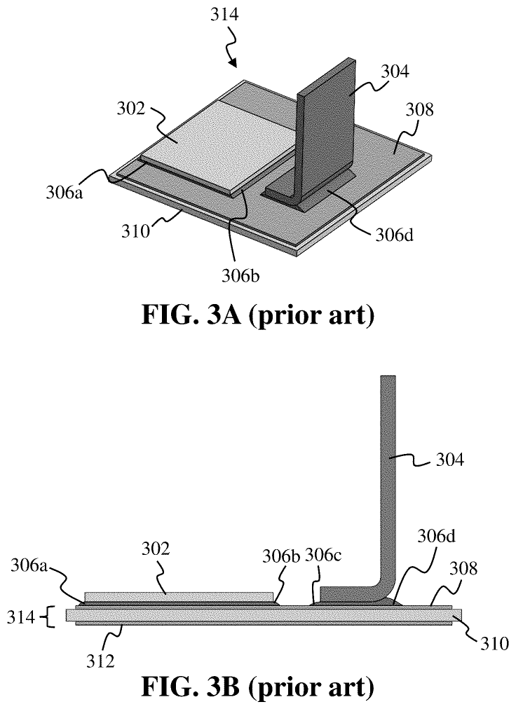

FIGS. 3A-3B are representative drawings showing soldering on power substrates, according to the prior art. FIG. 3A is a perspective view and FIG. 3B is a side view of a power substrate 314. The power substrate 314 consists of a first surface 308 and a second surface 312, with a ceramic tile 310 sandwiched therebetween. The power substrate 314 may thus be a DCB substrate, with the first surface 308 and second surface 312 being direct copper bonded material. Or the power substrate 314 may be an AMB substrate, with the first surface 308 and the second surface 312 being active metal brazed material. Disposed on the power substrate 314 is a power chip 302 (hereinafter, “chip 302”) and a power lead (terminal) 304 (hereinafter, “lead 304”), which are attached to the power substrate 314 using solder. Solder 306a and 306b are used to attach the chip 302 to the power substrate 314 while solder 306c and 306d are used to attach the lead 304 to the power substrate 314 (collectively, “solder 306”). The solders 306a-d may be regular solders, high-lead solders, lead-free solders, such as Ag-sintered, and so on. Or the solder 306a and 306b may be one type of solder while the solder 306c and 306d is a second type. Where the solders 306 are the same, the chip 302 and the lead 304 may be advantageously attached to the power substrate 314 in one process.

The solders 306c and 306d used to attach the lead 304 to the power substrate 314 may experience cold solder over time and in the presence of unfavorable environmental conditions. Where there is generally minimal thermo-mechanical stress on the chip 302, there may be significantly more thermo-mechanical stress on the lead 304, partly because the lead 304 is connected to an external circuit which might induce mechanical stress. Further, because both ends of the lead 304 are fixed, one side to the power substrate 314 and the other side to the external circuit, the lead 304 may experience higher thermo-mechanical stress during expansion and contraction which may occur over time. Thus, solder 306a and 306b on the chip 302 typically does not get stressed as much as solder 306c and 306d on the lead 304. The result may be an unreliable connection between the lead 304 and the power substrate 314. Since the lead 304 is connected to an external device, such as a busbar, other terminal, or PCB, the failure of the solders 306c or 306d will isolate the chip 302 from the rest of the circuitry and prevent it from functioning.

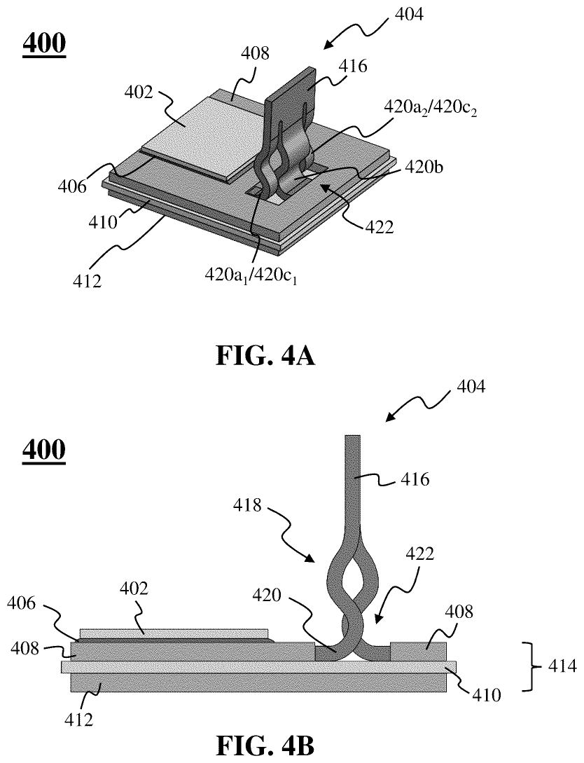

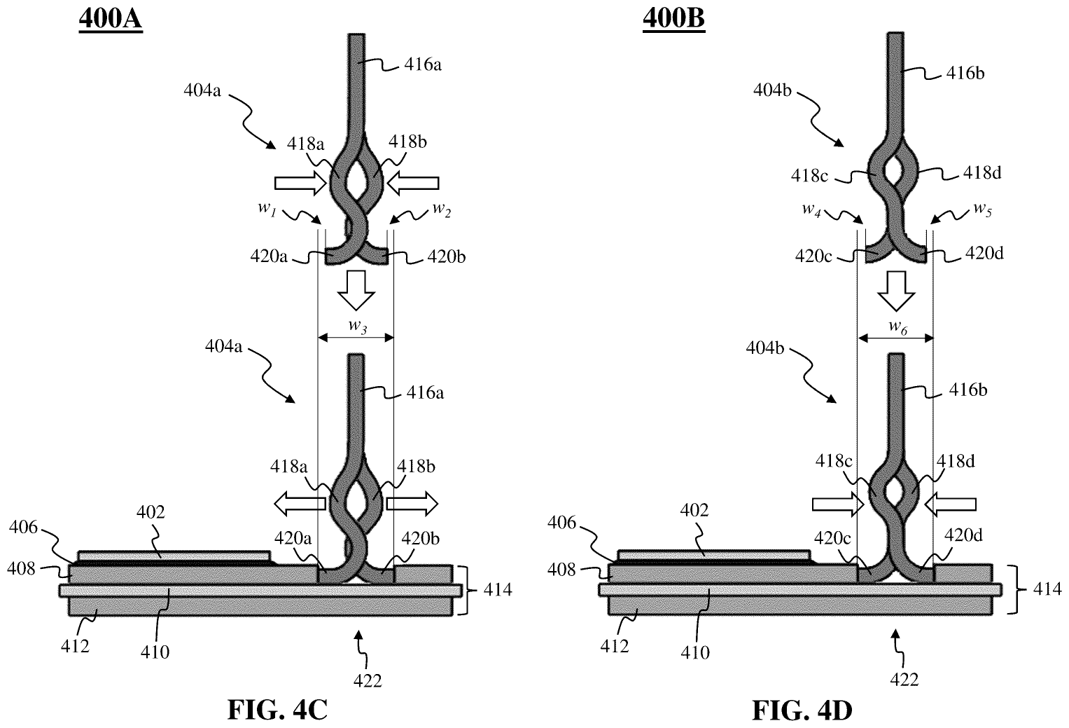

FIGS. 4A-4D are representative drawings of a pressure contact assembly 400, according to exemplary embodiments. FIG. 4A is a perspective view, FIG. 4B is a side view, and FIGS. 4C-4D are detailed side views of two different embodiments of the pressure contact assembly 400. The power substrate 414 consists of a first surface 408 and a second surface 412, with a ceramic tile 410 sandwiched therebetween. The power substrate 414 may thus be a DCB or an AMB substrate. In a non-limiting example, the pressure contact assembly 400 may alternatively be a single-sided power substrate 414, such as IMS. Disposed on the power substrate 414 is a power chip 402 (hereinafter, “chip 402”) and a power lead (terminal) 404 (hereinafter, “lead 404”), which are attached to the power substrate 414 using solder 406. Alternatively, the chip 402 may be attached to the power substrate 414 using Ag sintering.

The pressure contact assembly 400 utilizes 1) a cavity 422 formed in the power substrate 414; 2) a modification to the lead 404 to fit into the cavity 422; and optionally, 3) a modification to the ceramic tile 410 to facilitate successful connection between the lead 404 and the power substrate 414. The cavity 422 may be formed in a variety of ways known to those of skill in the art. In exemplary embodiments, the cavity 422 is formed by etching or otherwise cutting away the first surface 408 of the power substrate 414, exposing the ceramic tile 410 at the cavity 422. Alternatively, the first surface 408 may be partially etched away such that the ceramic tile 410 is not exposed at the cavity 422. In either case, the cavity 422 has sufficient depth to accommodate the base of the lead 404, as described further below.

In exemplary embodiments, the lead 404 consists of a top portion 416 and a bottom portion 420 in which the top portion 416 is split into two opposing sections. The bottom portion 420 further includes a pressure portion 418. FIGS. 4C-4D illustrate alternative pressure contact assemblies 400A and 400B, respectively (collectively, “pressure contact assembly 400” or “pressure contact assemblies 400”). Lead 404a consists of top portion 416a and bottom portions 420a and 420b, which include pressure portions 418a and 418b, respectively; lead 404b consists of top portion 416b and bottom portions 420c and 420d, which include pressure portions 418c and 418d, respectively (collectively, “top portion(s) 416”, “pressure portion(s) 418”, and “bottom portion(s) 420”). The top portion 416 looks like the top of lead 304. Thus, connecting the lead 404 to external circuitry is not impacted by the design change over the prior art.

The bottom portions 420 are curved like ribbon candy (with multiple waves) and are oppositional to one another (like mirror image S structures). Looking at the pressure contact assembly 400A (FIG. 4C), for example, bottom portion 420a extends downward from top portion 416a, curves to the left, curves to the right, then curves again to the left until being disposed horizontally (perpendicular to top portion 416a); bottom portion 420b also extends downward from top portion 416a, curves to the right, curves to the left, then curves again to the right until being disposed horizontally (perpendicular to top portion 416a). In exemplary embodiments, the top portion 416 is split into two different bottom portions 420a and 420b, with bottom portion 420a having two distinct parts, 420a₁ and 420a₂, as illustrated in FIG. 4A, where bottom portion 420b occupies the center of the lead 404, and bottom portions 420a₁ and 420a₂ are disposed on either side of bottom portion 420b. In FIGS. 4B-4D, bottom portion 420a₂ is not visible, being “behind” the other bottom portions 420a₁ and 420b. Thus, for both the pressure contact assemblies 400A and 400B, the top portion 416 of the lead 404 is split into a first s-shaped section 416a₁/416c₁, a second s-shaped section 416b, and a third s-shaped section 416a₂/416c₂, where the second s-shaped section 416b is disposed between the first s-shaped section 416a₁/416c₁ and the third s-shaped section 416a₂/416c₂, and the second s-shaped section 416b is a mirror image of the first s-shaped section 416a₁/416c₁ and the third s-shaped section 416a₂/416c₂.

The result of this design is a lead 404a that has movement in the form of spring action. In exemplary embodiments, by pushing the bottom portions 420a and 420b toward one another at pressure portions 418a and 418b, respectively, this causes bottom portions 420a and 420b to move toward one another. The lead 404a thus has a resting state (bottom of FIG. 4C) and a compressed state (top of FIG. 4C). Bottom portion 420a can move a width, w₁, in a leftward direction while bottom portion 420b is able to move a width, w₂, in a rightward direction, where widths w₁ and w₂ may be equal (w₁=w₂) or not equal (w₁≠w₂). Cavity 422 has a width, w₃. In the resting state of lead 404a, the distal ends of bottom portions 420a and 420b are a width, w₃, apart while, in the compressed state of lead 404a, bottom portions 420a and 420b are a width, w₃−(w₁+w₂) apart.

To attach the lead 404a to the power substrate 414, the pressure portions 418a and 418b are pressed toward one another, causing the lead 404a to be in its compressed state. The lead 404 is then moved downward toward the cavity 422 until the bottom portions 420a and 420b touch the bottom of the cavity 422. The pressure portions 418a and 418b are then released so that they spring back until the lead 404 is in its resting state. In exemplary embodiments, horizontal pressure is applied to the pressure portions 418a and 418b to make a solderless contact between bottom portions 420a and 420b and to the wall of cavity 422, ensuring a tight coupling therebetween without need of solder. The lead 404 is thus fastened to the power substrate 414.

The pressure contact assembly 400B (FIG. 4D) is slightly different than the pressure contact assembly 400A. Bottom portion 420c extends downward from top portion 416b and curves to the right, then curves slightly to the left, extends vertically downward, then curves to the left in a horizontal disposition; bottom portion 420d also extends downward from top portion 416b and curves to the left, then curves slightly to the right, extends vertically downward, then curves to the right in a horizontal disposition. In exemplary embodiments, the top portion 416b is split into bottom portions 420c and 420d, with bottom portion 420c having two distinct parts, 420c₁ and 420c₂, as illustrated in FIG. 4A, where bottom portions 420c₁ and 420c₂ are disposed on either side of bottom portion 420b. In FIGS. 4B-4D, bottom portion 420c₂ is not visible, being “behind” the other bottom portions 420c₁ and 420b. The base of bottom portions 420c and 420d are thus orthogonal to the top portion 416b.

Like lead 404a, lead 404b has movement in the form of spring action. In exemplary embodiments, by pushing the pressure portions 418c and 418d toward one another, this causes bottom portions 420c and 420d to move away from one another. The lead 404b thus has a resting state (top of FIG. 4D) and an expanded state (bottom of FIG. 4D). Bottom portion 420c can move a width, w₄, in a leftward direction while bottom portion 420d is able to move a width, w₅, in a rightward direction, where widths w₄ and w₅ may be equal (w₄=w₅) or not equal (w₄≠w₅). Cavity 422 has a width, w₆. In the resting state of lead 404b, the distal ends of bottom portions 420c and 420d are a width, w₆−(w₄+w₅) apart while, in the expanded state of lead 404b, bottom portions 420c and 420d are a width, w₆ apart.

To attach the lead 404b to the power substrate 414, the lead 404b is first moved downward until the bottom portions 420c and 420d are inside the cavity 422. Pressure portions 418c and 418d are pressed toward one another, causing the bottom portions 420c and 420d to move and remain apart (the expanded state). In exemplary embodiments, horizontal pressure is applied to the pressure portions 418c and 418d to make a solderless contact between bottom portions 420c and 420d and to the wall of the cavity 422, ensuring a tight coupling therebetween without need of solder.

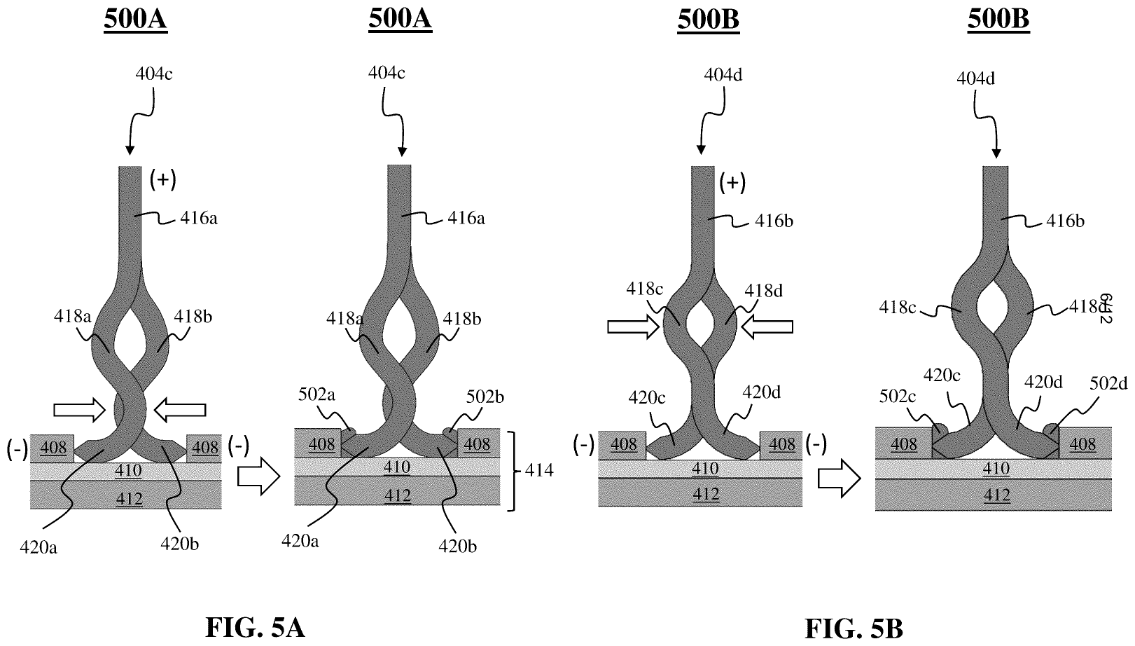

FIGS. 5A-5B are representative drawings of pressure contact assemblies 500A and 500B, according to exemplary embodiments. FIG. 5A presents side views of pressure contact assembly 500A while FIG. 5B presents side views of pressure contact assembly 500B. Pressure contact assembly 500A is the pressure contact assembly 400A, modified to include resistance welding; pressure contact assembly 500B is the pressure contact assembly 400B, modified to include resistance welding (collectively, “pressure contact assembly 500” or “pressure contact assemblies 500”). Join terminals 502a and 502b are shown in FIG. 5A while join terminals 502c and 502d are shown in FIG. 5B (collectively, “join terminal(s) 502”). In exemplary embodiments, resistance welding is performed at the join terminals 502, causing the bottom portions 420 of the respective leads 404 to soften/melt. Resistance welding is the joining of metals by applying pressure and passing current through the metal area to be joined. No additional materials such as solder, are needed to melt the bottom portions 420 against the first surface 408 of the power substrate 414. Resistance welding is done at high current (typically, greater than 110 A) with lower voltage (typically, 4˜12 V) in which the two-input terminal either (+) or (−) can be at any position.

The following pressure contact assemblies are characterized as having L-shaped power leads (terminals) in which the top portion is for connection to an external device. The bottom portion, which is perpendicular to the top portion, includes one or more modifications from being an otherwise smooth surface. The one or more modified portions of the lead are press-fit into the power substrate. The surfaces of each power substrate have likewise been over-etched, under-etched, and/or half-etched to receive the modified portions of the lead. In some cases, additional pressure devices, such as part of the housing of the pressure contact assembly, are used to facilitate the press-fitting operation.

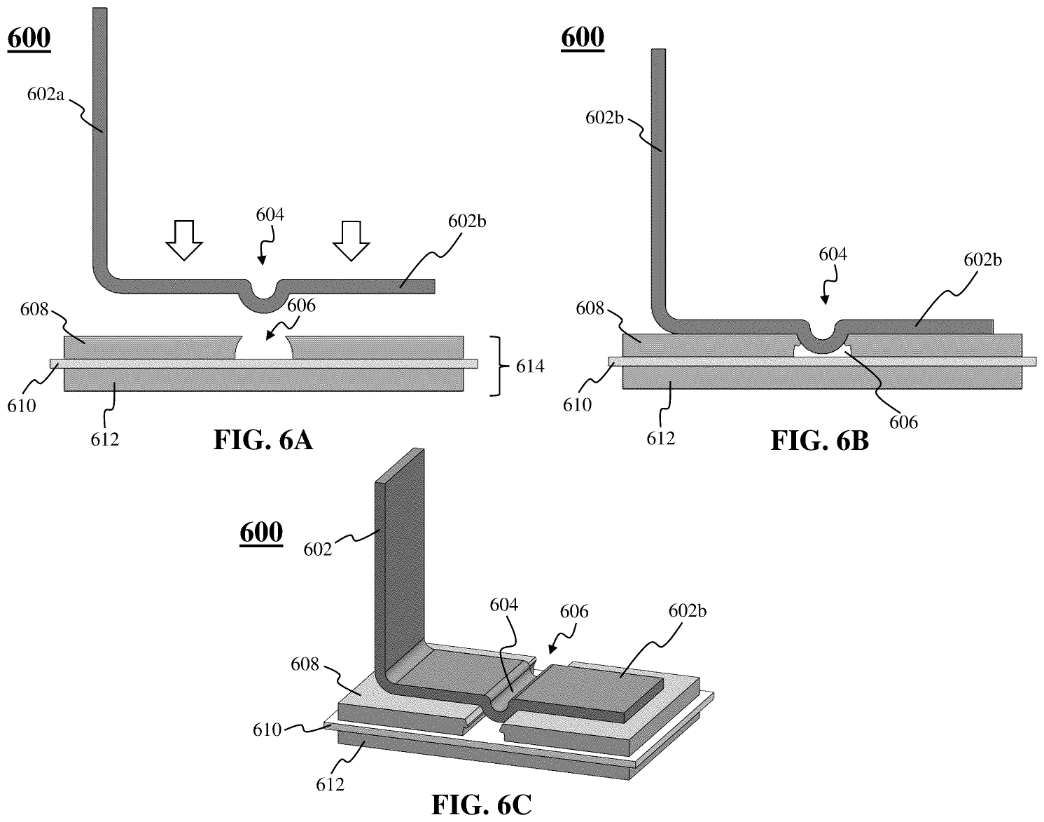

FIGS. 6A-6C are representative drawings of a pressure contact assembly 600, according to exemplary embodiments. FIGS. 6A-6B are side views and FIG. 6C is a perspective view of the pressure contact assembly 600. In exemplary embodiments, a power lead (terminal) has two portions 602a and 602b (collectively, “lead(s) 602”), with lead portion 602a being orthogonal to lead portion 602b, forming an “L shape”. The lead 602 is to be attached to a power substrate 614 consisting of a first surface 608 and a second surface 612, with a ceramic tile 610 sandwiched therebetween. Once attached, lead portion 602a is orthogonal to the power substrate 614 while lead portion 602b is adjacent the power substrate 614. In exemplary embodiments, the modification to the otherwise smooth surface of the lead portion 602b is a coining u-shape 604 for attachment to the power substrate 614.

Additionally, in exemplary embodiments, an over-etch 606 is cut into the power substrate 614, specifically, the first surface 608. The over-etch 606 is defined herein as a cut through the first surface 608 until the ceramic tile 610 is visible. Further, the over-etch 606 is wider at the bottom than at the top of the first surface 608. In exemplary embodiments, the lead 602 is placed over the power substrate 614 until the coining u-shape 604 is disposed over the over-etch 606. Pressure is applied to the lead portion 602b until the coining u-shape 604 fits into the over-etch 606. Alternatively, the coining u-shape 604 may be slid into the over-etch 606, from the back of the power substrate 614 or from the front. The first surface 608 will deform somewhat around the coining u-shape 604, causing the lead 602 to be permanently attached to the power substrate 614 without using solder. The lead 602 is thus fastened to the power substrate 614.

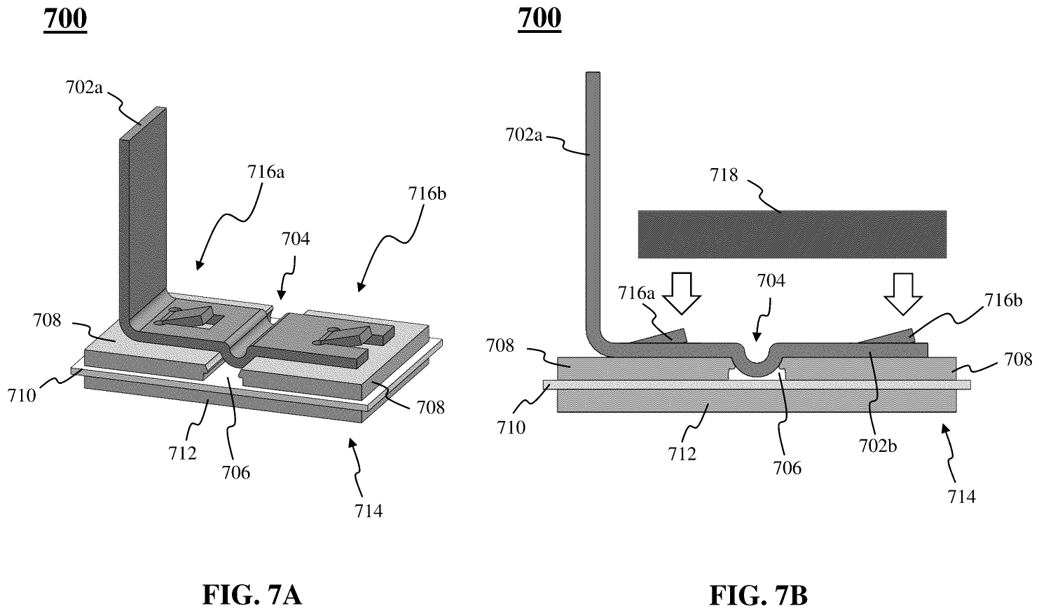

FIGS. 7A-7B are representative drawings of a pressure contact assembly 700, according to exemplary embodiments. FIG. 7A is a perspective view and FIG. 7B is a side view of the pressure contact assembly 700. Like the pressure contact assembly 600, the pressure contact assembly 700 features a power lead (terminal) having two portions 702a and 702b (collectively, “lead(s) 702”), with lead portion 702a being orthogonal to lead portion 702b, forming an “L shape”. The lead 702 is to be attached to a power substrate 714 consisting of a first surface 708 and a second surface 712, with a ceramic tile 710 sandwiched therebetween. In exemplary embodiments, the modification to the otherwise smooth surface of the lead portion 602b is also a coining u-shape 704 for attachment to the power substrate 714. An over-etch 706 is cut into the power substrate 714 until the ceramic tile 710 is visible.

In exemplary embodiments, lead portion 702b further includes spring contacts 716a and 716b (collectively, “spring contact(s) 716”). The spring contacts 716 are sections of the lead portion 702b that have been cut, then bent upward. In a non-limiting example, the cutout sections are generally rectangular in shape, forming the spring contacts 716. In exemplary embodiments, housing 718 of the pressure contact assembly 700 pushes against the spring contacts 716, thus providing constant pressure to the lead 702, without need of solder. The lead 702 is thus fastened to the power substrate 714.

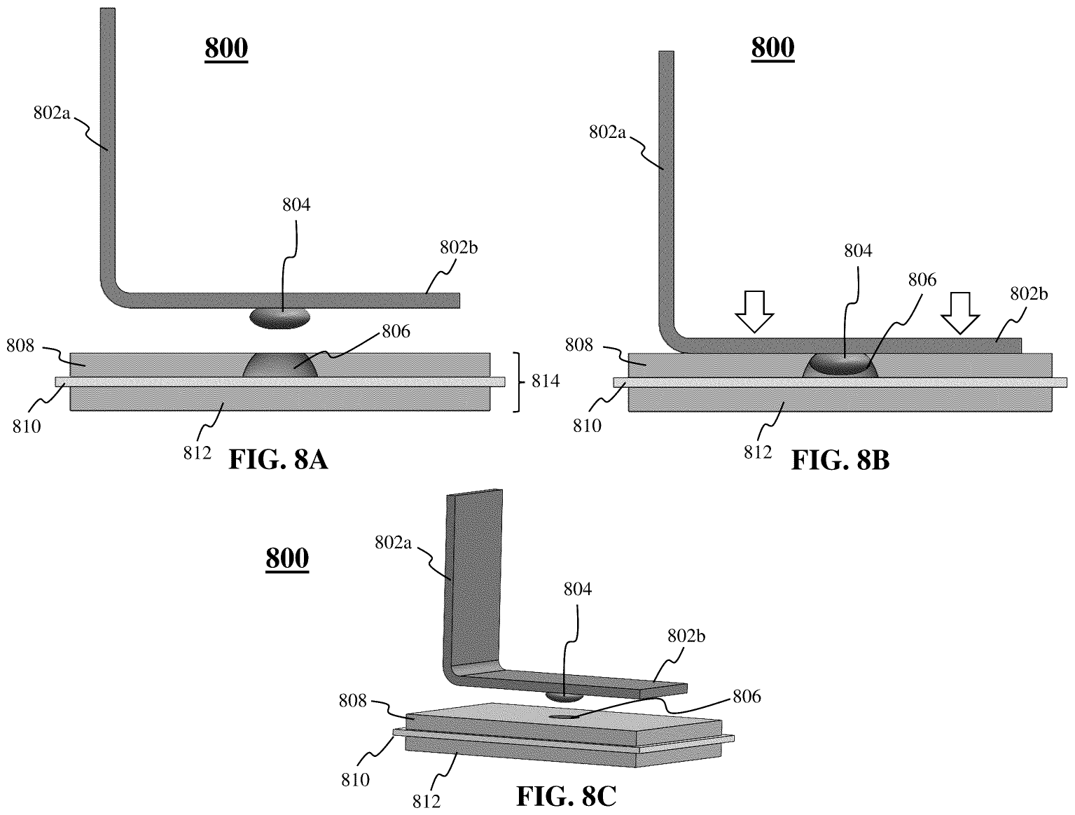

FIGS. 8A-8C are representative drawings of a pressure contact assembly 800, according to exemplary embodiments. FIGS. 8A-8B are side views and FIG. 8C is a perspective view of the pressure contact assembly 800. In exemplary embodiments, a power lead (terminal) has two portions 802a and 802b (collectively, “lead(s) 802”), with lead portion 802a being orthogonal to lead portion 802b, forming an “L shape”. The lead 802 is to be attached to a power substrate 814 consisting of a first surface 808 and a second surface 812, with a ceramic tile 810 sandwiched therebetween. Once attached, lead portion 802a is orthogonal to the power substrate 814 while lead portion 802b is adjacent the power substrate 814. In exemplary embodiments, the modification to the otherwise smooth surface of the lead portion 802b is a button 804 for attachment to the power substrate 814. The button 804 is an addition to the lead portion 802b. In exemplary embodiments, the button 804 is a copper stud that is attached to a bottom surface of the lead portion 802b, such as by laser welding.

In exemplary embodiments, an over-etch 806 is cut into the power substrate 814, specifically, the first surface 808. The over-etch 806 is cut through the first surface 808 until the ceramic tile 810 is visible. Further, the over-etch 806 is wider at the bottom than at the top of the first surface 808. In exemplary embodiments, the lead 802 is placed over the power substrate 814 until the button 804 is disposed over the over-etch 806. Pressure is applied to the lead portion 802b until the button 804 fits into the over-etch 806. Alternatively, the button 804 may be slid into the over-etch 806, from the back of the power substrate 814 or from the front. The first surface 808 will deform somewhat around the button 804, causing the lead 802 to be permanently attached to the power substrate 814 without using solder. The lead 802 is thus fastened to the power substrate 814.

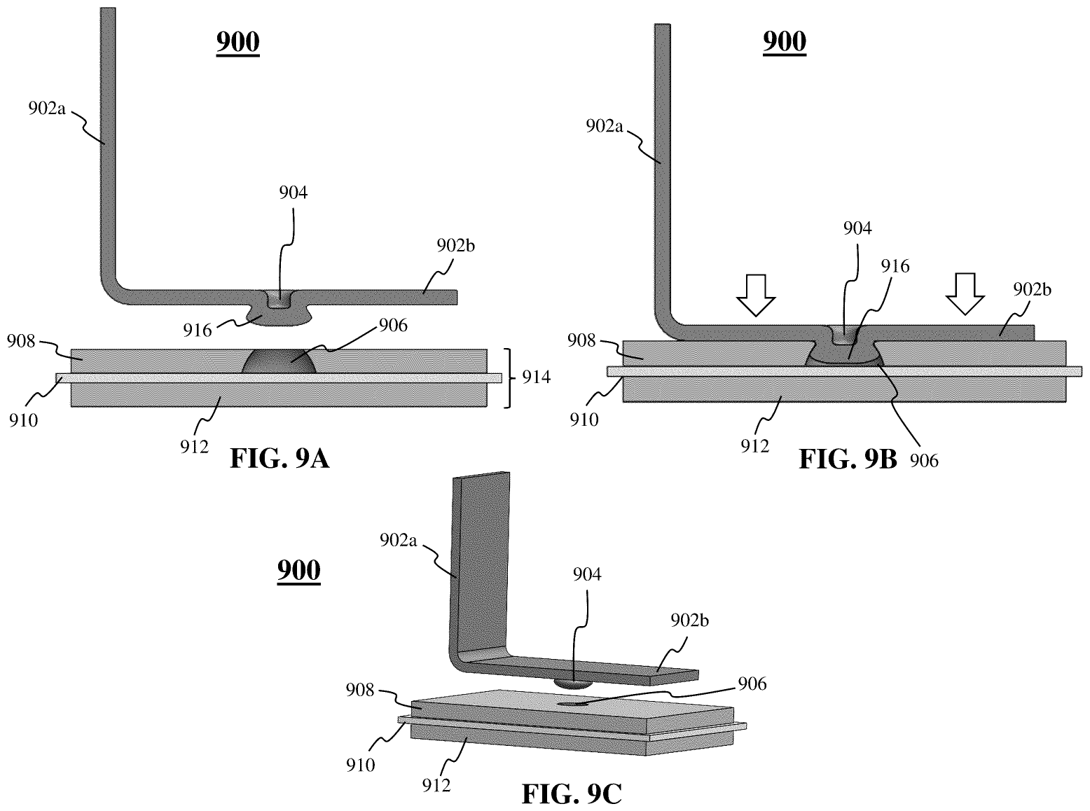

FIGS. 9A-9C are representative drawings of a pressure contact assembly 900, according to exemplary embodiment. FIGS. 9A-9B are side views and FIG. 9C is a perspective view of the pressure contact assembly 900. In exemplary embodiments, a power lead (terminal) has two portions 902a and 902b (collectively, “lead(s) 902”), with lead portion 902a being orthogonal to lead portion 902b, forming an “L shape”. The lead 902 is to be attached to a power substrate 914 consisting of a first surface 908 and a second surface 912, with a ceramic tile 910 sandwiched therebetween. Once attached, lead portion 902a is orthogonal to the power substrate 914 while lead portion 902b is adjacent the power substrate 914. In exemplary embodiments, the modification to the otherwise smooth surface of the lead portion 902b is a deformation 904 in the top of the lead portion 902b, which causes a protrusion 916 beneath the lead portion 902b, where the protrusion 916 is for attachment to the power substrate 914. The deformation 904 and protrusion 916 are extensions of the lead portion 902b, which are achieved, in some embodiments, by coining, embossing, or blanking.

In exemplary embodiments, an over-etch 906 is cut into the power substrate 914, specifically, the first surface 908. The over-etch 906 is cut through the first surface 908 until the ceramic tile 910 is visible. Further, the over-etch 906 is wider at the bottom than at the top of the first surface 908. In exemplary embodiments, the lead 902 is placed over the power substrate 914 until the deformation 904 and protrusion 916 are disposed over the over-etch 906. Pressure is applied to the lead portion 902b until the protrusion 916 fits into the over-etch 906. Alternatively, the protrusion 916 may be slid into the over-etch 906, from the back of the power substrate 914 or from the front. The first surface 908 will deform somewhat around the protrusion 916, causing the lead 902 to be permanently attached to the power substrate 914 without using solder. The lead 902 is thus fastened to the power substrate 914.

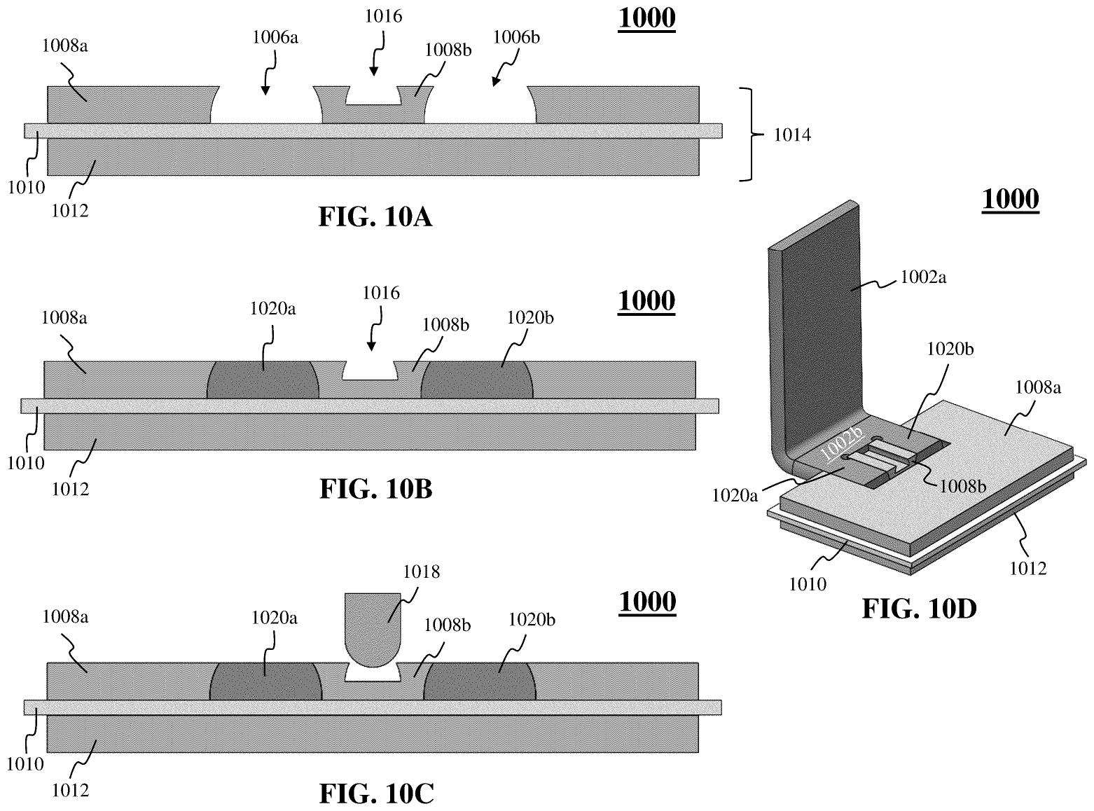

FIGS. 10A-10D are representative drawings of a pressure contact assembly 1000, according to exemplary embodiments. FIGS. 10A-10C are side views while FIG. 10D is a perspective view of the pressure contact assembly 1000. In exemplary embodiments, a power lead (terminal) has two portions 1002a and 1002b (collectively, “lead(s) 1002”), with lead portion 1002a being orthogonal to lead portion 1002b, forming an “L shape”. The lead 1002 is to be attached to a power substrate 1014 consisting of a first surface consisting of two portions 1008a and 1008b (collectively, “first surface 1008”) and a second surface 1012, with a ceramic tile 1010 sandwiched therebetween. Once attached, lead portion 1002a is orthogonal to the power substrate 1014 while lead portion 1002b is adjacent the power substrate 1014. In exemplary embodiments, the modification to the otherwise smooth surface of the lead portion 1002b is the cutting away of a center portion (center cut) of the lead portion 1002b, resulting in a pair of “feet” 1020a and 1020b (singularly, “foot 1020”, collectively, “feet 1020”) that are used to attach the lead 1002 to the power substrate 1014.

In exemplary embodiments, over-etches 1006a and 1006b (collectively, “over-etch(es) 1006”) are cut into the power substrate 1014, specifically, the first surface 1008. The over-etches 1006 are cut through the first surface 1008 until the ceramic tile 1010 is visible. Further, the over-etches 1006 are wider at the bottom than at the top of the first surface 1008. In exemplary embodiments, the feet 1020 of the lead 1002 are slid into the power substrate 1014 until the foot 1020a fits into over-etch 1006a and foot 1020b fits into over-etch 1006b.

The first surface 1008 of the power substrate 1014 has two parts, a first portion 1008a and a second portion 1008b. In exemplary embodiments, between the two over-etches 1006a and 1006b is an under-etch 1016. The under-etch 1016 is defined herein as a cut into the first surface 1008 that does not reach the ceramic tile 1010 below. In this example, the under-etch 1016 is cut into the second portion 1008b of the first surface. In contrast to the over-etches 1006a and 1006b, the under-etch 1016 is not cut all the way to the ceramic tile 1010. A pressure device 1018 is shown, which could be a part of the housing of the pressure contact assembly 1000. By applying pressure to the under-etch 1016, the second portion 1008b will deform somewhat around the two feet 1020 of the lead 1002, causing the lead 1002 to be permanently attached to the power substrate 1014 without using solder. In exemplary embodiments, as feet 1020a and 1020b are slid into respective over-etches 1006a and 1006b, mechanical pressure may be applied to the under-etch 1016 which deforms the second portion 1008b of the first surface 1008, resulting in a tight coupling of between the lead 1002 and the power substrate 1014.

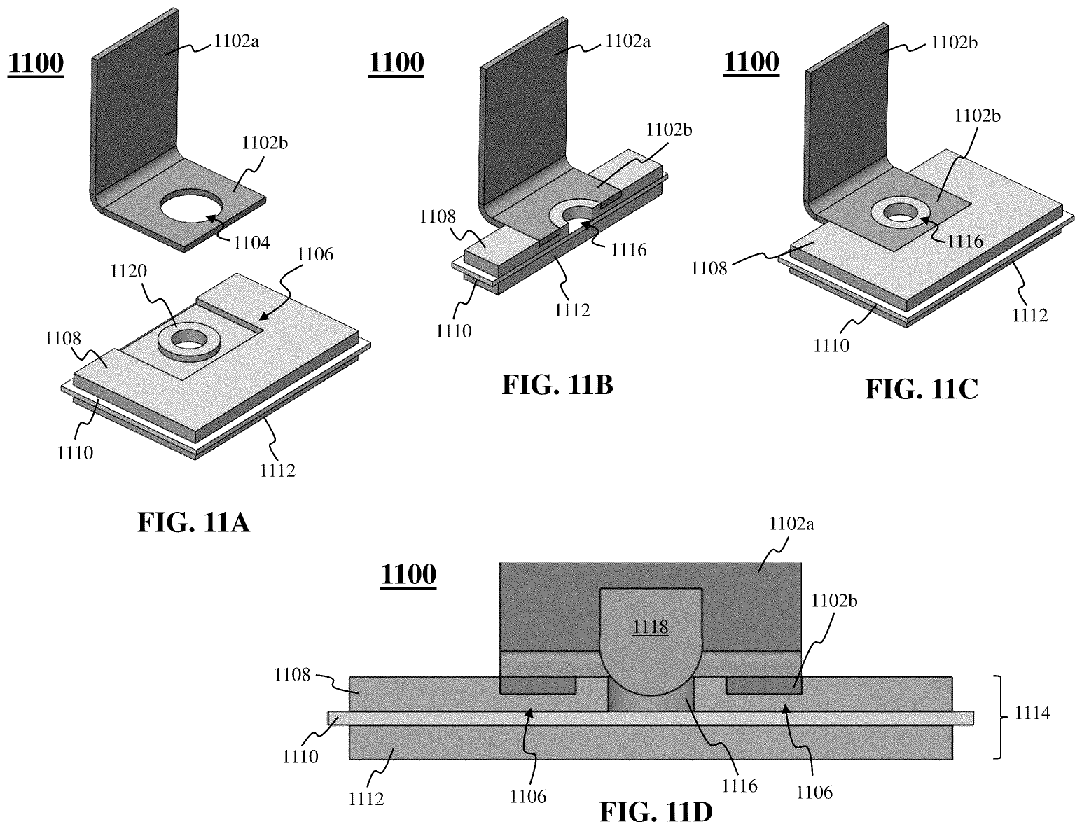

FIGS. 11A-11D are representative drawings of a pressure contact assembly 1100, according to exemplary embodiments. FIGS. 11A-11C are perspective views and FIG. 11D is a side view of the pressure contact assembly 1100. In exemplary embodiments, a power lead (terminal) has two portions 1102a and 1102b (collectively, “lead(s) 1102”), with lead portion 1102a being orthogonal to lead portion 1102b, forming an “L shape”. The lead 1102 is to be attached to a power substrate 1114 consisting of a first surface 1108 and a second surface 1112, with a ceramic tile 1110 sandwiched therebetween. Once attached, lead portion 1102a is orthogonal to the power substrate 1114 while lead portion 1102b is adjacent the power substrate 1114. In exemplary embodiments, lead portion 1102b is the portion of the lead 1102 being attached to the power substrate 1114. In exemplary embodiments, the modification to the otherwise smooth surface of the lead portion 1102b is an aperture 1104 cut through the lead portion 1102b.

In exemplary embodiments, an under-etch 1106 and an over-etch 1116 are cut into the power substrate 1114, specifically, the first surface 1108. In some embodiments, the under-etch 1116 is a half-etch, meaning that half of the first surface 1108 is etched away. The under-etch 1106 is a rectangular cutout of the first surface 1108 that is not cut all the way to the ceramic tile 1110, while the over-etch 1116 is cut through the first surface 1108 until the ceramic tile 1110 is visible. In a non-limiting example, the under-etch 1106 is rectangular while the over-etch 1116 is circular. Further, there is a circular portion 1120 of the first surface 1108 that is not etched between the under-etch 1106 and the over-etch 1116. In exemplary embodiments, the circular portion 1120 is approximately the same diameter as the aperture 1104.

In exemplary embodiments, the lead 1102 is disposed over the power substrate 1114 until the aperture 1104 fits over the circular portion 1120. The dimension of the lead portion 1102b is approximately the same as the dimension of the under-etch 1106.

A pressure device 1118 is shown, which may be a part of the housing of the pressure contact assembly 1100. By applying pressure to the over-etch 1116, the circular portion 1120 will deform somewhat around the lead portion 1102b, causing the lead 1002 to be permanently attached to the power substrate 1114 without using solder. In exemplary embodiments, as lead portions 1102b is inserted into the into the under-etch 1106, mechanical pressure may be applied to the over-etch 1116 which deforms the circular portion 1120 of the first surface 1108, resulting in a tight coupling of between the lead 1102 and the power substrate 1114.

Table 1 provides a comparison between materials used in power substrates versus using the pressure contact assemblies (400, 500, 600, 700, 800, 900, 1000, and 1100). K88 is a leadframe manufacturer that uses copper and alloys to make the lead terminals both strong and flexible, resulting in a spring-like quality to the leads. Rthjc is the impedance from junction to case (outside surface of package). In exemplary embodiments, the leads for the above-described pressure contact assemblies 400, 500, 600, 700, 800, 900, 1000, and 1100 are impregnated with a material to make the leads springier yet maintain hardness. Where lead frames typically have a hardness vector (HV) of 100 to 130, in exemplary embodiments, the pressure contact assemblies 400, 500, 600, 700, 800, 900, 1000, and 1100. Further, in exemplary embodiments, where prior art power substrates typically used Aluminum Oxide (Al₂O₃), Aluminum Nitride (AlN), or Zirconia Toughened Alumina (ZTA), the pressure contact assemblies 400, 500, 600, 700, 800, 900, 1000, and 1100 utilize ceramic made of Si₃N₄ (Silicon Nitride) for better performance rather than AlN.

TABLE 1
Comparison between prior art and new technology

| Prior art | Disclosed art | Advantage |
|---|---|---|
| Uses industry | Uses K88 harder leadframe | Sturdy |
| standard softer | material (140~170 hardness | leadframe, hard |
| copper material | value) or equivalent material | wearing |
| like TAMACA, | due to pressured contact | |
| KFC, 12Sn, | requirement when inserted | |
| PMC90 | into power substrate cavity | |
| Uses standard | Uses high-performance | High current carrying |
| substrate Al₂0₃ | substrate, AMB Si₃N₄ | capability; no ceramic |
| or AlN DCB | | crack issue due to |
| | | high bending |
| | | strength and toughness |
| Soldered power | No solder connection | High reliability |
| terminal | | performance due to the |
| | | absence of solder; |
| | | high current carrying |
| | | capability |
| Press fit pin | Pressured contact to | Disclosed art is inside |
| to PCB | DCB/AMB/IMS | package while prior |
| | | art is outside package |

In exemplary embodiments, the ceramic tile used for the power substrate in the pressure contact assemblies 400, 500, 600, 700, 800, 900, 1000, 1100 is modified from prior art power assemblies to enhance the strength of the power substrate. Table 2 provides characteristic data about the ceramic tile. In exemplary embodiments, thermal conductivity, bending strength, and fracture toughness are all considered when selecting the ceramic tile for the pressure contact assemblies 400, 500, 600, 700, 800, 900, 1000, 1100. In exemplary embodiments, the ceramic tiles are made using Silicon Nitride (Si₃N₄), also known as high-performance AMB substrate with a favorable combination to thermal conductivity, bending strength, and toughness, as compared to standard Al₂O₃, AlN, or ZTA. In addition, only AMB can achieve a thicker layer of copper to ceramic tile through brazing because, by “bonding process”, the proven thickness of the copper layer is only 0.50 mm maximum, as compared to AMB of 0.8 mm, which is ideal for a solderless connection to form the cavity (e.g., cavity 422 in FIGS. 4A-4D) in the copper surface (e.g., first surface 408 of power substrate 414).

TABLE 2
Characteristics of ceramic tile

| | Al₂0₃ 96% | AlN | ZTA (9%) | Si₃N₄ |
|---|---|---|---|---|
| Thermal conductivity (W/mK) | 24 | 180 | 28 | 90 |
| Bending strength (MPa) | 450 | 300 | 700 | 650 |
| Fracture toughness (MPa/√m) | 3, 8-4, 2 | 3-3, 4 | 4, 5-5 | 6, 5-7 |

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

While the present disclosure makes reference to certain embodiments, numerous modifications, alterations, and changes to the described embodiments are possible without departing from the sphere and scope of the present disclosure, as defined in the appended claim(s). Accordingly, it is intended that the present disclosure not be limited to the described embodiments, but that it has the full scope defined by the language of the following claims, and equivalents thereof.

1. A pressure contact assembly comprising:
a power substrate comprising a first surface coupled to a ceramic tile, the first surface comprising a first cavity;
a chip soldered onto the first surface; and
a lead to be inserted into the first cavity, the lead comprising:
a top portion to connect to an external device; and
a bottom portion with a modified portion to fit into the first cavity.

2. The pressure contact assembly of claim 1, wherein the modified portion includes a coining u-shaped.

3. The pressure contact assembly of claim 2, wherein the modified portion includes a spring contact, and wherein pressure is applied to the spring contact to fit the coining u-shape into the first cavity.

4. The pressure contact assembly of claim 1, wherein the modified portion includes a button.

5. The pressure contact assembly of claim 1, wherein the modified portion includes a deformation.

6. The pressure contact assembly of claim 1, the first surface further comprising:
a second cavity; and
an under-etch disposed between the first cavity and the second cavity,
wherein pressure is applied to the under-etch to fasten the lead into the power substrate.

7. The pressure contact assembly of claim 1, wherein the modified portion includes an aperture, wherein the first cavity is an under-etch comprising a rectangular cutout of the first surface that does not expose the ceramic tile, wherein the first surface includes an over-etch cut through the first surface until the ceramic tile is visible, wherein the first surface includes a circular portion between the under-etch and the over-etch, and wherein the aperture fits over the circular portion to fasten the lead into the power substrate.

8. The pressure contact assembly of claim 1, wherein the ceramic tile is visible at the first cavity.

9. The pressure contact assembly of claim 1, further comprising:
a second surface,
wherein the ceramic tile is sandwiched between the first surface and the second surface.

10. The pressure contact assembly of claim 9, wherein the power substrate is a direct copper bonded substrate.

11. The pressure contact assembly of claim 9, wherein the power substrate is an active metal brazed substrate.

12. The pressure contact assembly of claim 1, wherein the power substrate is an insulated metal substrate.

13. A pressure contact assembly comprising:
a power substrate comprising a first surface coupled to a ceramic tile, the first surface comprising a cavity; and
a lead comprising:
a first portion to connect to an external device; and
a second portion coupled to the first portion, the second portion being perpendicular to the first portion, and the second portion comprising a modification, wherein the modification is press-fit into the cavity.

14. The pressure contact assembly of claim 13, wherein the modification is selected from a group consisting of a coining u-shape, a button, a deformation causing a protrusion, a center cut resulting in a pair of feet, and an aperture.

15. The pressure contact assembly of claim 13, wherein the cavity is selected from a group consisting of an over-etch, an under-etch, and a half-etch.

16. The pressure contact assembly of claim 13, wherein the power substrate is selected from a group consisting of a direct copper bonded substrate, an active metal brazed substrate, and an insulated metal substrate.

17. The pressure contact assembly of claim 13, wherein the ceramic tile is Silicon Nitride (Si₃N₄).
